(19) United States
(12) Patent Application Publication
(10) Pub. No.: US 2001/0017412 A1
(43) Pub. Date: Aug. 30, 2001

(54) Semiconductor device

(76) Inventors: Takuro Asazu, Nara-shi (JP); Atsushi Ono, Yamatokoriyama-shi (JP); Shinji Yamaguchi, Tenri-shi (JP)

Correspondence Address: NIXON & VANDERHYE P.C., 8th Floor, 1100 North Glebe Rd., Arlington, VA, 22201-4714, US

(21) Appl. No.: 09/729,184

(22) Filed: Dec. 5, 2000

(30) Foreign Application Priority Data
Feb. 24, 2000 (JP) 2000-047670

(51) Int. Cl. H01L 23/48; H01L 23/52; H01L 29/40

(52) U.S. Cl. 257/737; 257/738; 257/741; 257/748; 257/766; 257/772; 257/779; 257/781; 257/784

(57) ABSTRACT

Formed on the semiconductor chip surface are electrode pads, on which electroless Ni plated bumps are formed. The electroless Ni plated bumps are arranged in at least two rows in parallel with the two sides of the semiconductor chip, opposing each other. Each electroless Ni bump is 5 μm or more in height and the surface is coated with Au plating as a metal film. The surface of the conductor leads is coated with Sn plating. The conductor leads and bumps are heated and pressed by a bonding tool to crate Au/Sn eutectic alloy junctions.

### BACKGROUND OF THE INVENTION

(1) Field of the Invention

The present invention relates to a semiconductor device having a semiconductor chip with bumps connected to a conductor pattern formed on a substrate, and in particular relates to a semiconductor device suitable for tape carrier package and the like.

(2) Description of the Prior Art

The prior art will be explained referring to an example of a tape carrier package (to be referred as ‘TCP’ hereinbelow). The TCP is one of the most advantageous configurations for packaging a semiconductor device with multiple connecting terminals compactly. Further, because the TCP has good flexibility and can be flexed freely, at present it is widely used for packages and the like of liquid crystal panel driver ICs.

FIG. 1 shows a state where a conductor lead 61 of a prior art TCP configuration and an electrolyte Au plated bump 53 are connected. In FIG. 1, an electrode pad 52 and electrolyte Au plated bump 53 are formed on a semiconductor chip 51. Conductor lead 61 of the tape carrier is coated by a Sn plating 62 so as to form Au/Sn eutectic alloy 54 with electrolyte Au plated bump 53. Here, 63 designates the bonding tool, which applies heat and pressure at the connecting portions.

In the conventional TCP for LCD panel drivers, semiconductor chips 51 formed with electrolyte Au plated bumps 53 consisting of pure Au have been used. Formation of electrode bumps by electrolyte Au plating has the advantages of high productivity owing to wafer batch processing and fabrication of fine-pitch bump products of up to 50 μm pitch bumps, hence is widely used for fabrication of semiconductor devices for LCD panel drivers.

In order to deal with recent, severe cost demands in the market for LCD panel driver ICs, in the field of the conventional semiconductor chips using electrolyte Au plated bumps, as a reduction in cost, the amount of Au used has been reduced by making the height of bumps lower and the size of bumps smaller. However, the attempt to lower the height of the bumps and reduce the size of the bumps is approaching its limit. Further, increase in the amount of Au used per semiconductor chip due to increase of the number of electrode pads accompanying the recent multi-functional tendency of semiconductor chips is a heavy factor in impeding cost reduction in the conventional electrolyte Au bump process in which the electrode bumps are composed of pure Au. Further, as wafers have become greater as 8 inches and 12 inches, investment in plant and equipment for the electrolyte Au plated bump fabrication line has become extremely large.

### SUMMARY OF THE INVENTION

It is therefore an object of the present invention to provide a semiconductor device which can be manufactured with a reduced cost, sill using the conventional assembly process, by using a cheaper material for bumps instead of using Au as used heretofore and by providing metal films on both the bump and conductor lead to enable stable connection between the bumps and conductor leads.

In order to achieve the above object, the present invention is configured as follows:

In accordance with the first aspect of the present invention, a semiconductor device in which bumps formed on a semiconductor chip and a conductor pattern formed on a substrate are connected, is characterized in that

the bump is comprised of Ni and a metal film having a thickness falling within a specified range, formed over Ni;

the conductor pattern is coated with a metal film having a thickness falling within a specified range; and

the connection is formed by alloying the metal films.

In accordance with the second aspect of the present invention, the semiconductor device having the above first feature is characterized in that the metal film on the bumps is Au and the metal film on the conductor pattern is Sn.

In accordance with the third aspect of the present invention, the semiconductor device having the above first feature is characterized in that the metal film on the bumps is Sn and the metal film on the conductor pattern is Au.

In accordance with the fourth aspect of the present invention, the semiconductor device having the above second feature is characterized in that the metal film of Au is 0.5 to 3.0 μm thick and the metal film of Sn is 0.09 to 0.19 μm thick.

In accordance with the fifth aspect of the present invention, the semiconductor device having the above third feature is characterized in that the metal film of Au is 0.5 to 3.0 μm thick and the metal film of Sn is 0.09 to 0.19 μm thick.

The present invention enables application of semiconductor chips having Ni bumps formed on electrode pads to semiconductor devices by providing stable alloy junction between the semiconductor chip and conductor leads. As a result, Ni can become used as the material of the electrode bumps of the semiconductor chip in place of Au, which has been conventionally used, thus making it possible to sharply reduce the use amount of Au. In this way, the invention is able to reduce the cost sharply compared to the conventional semiconductor device, while forming junctions equivalent to those formed when Au bumps are used.

### BRIEF DESCRIPTION OF THE DRAWINGS

FIG. 1 is a sectional view showing the connected state of a conductor lead of a prior art tape carrier configuration with an electrolyte Au plated bump;

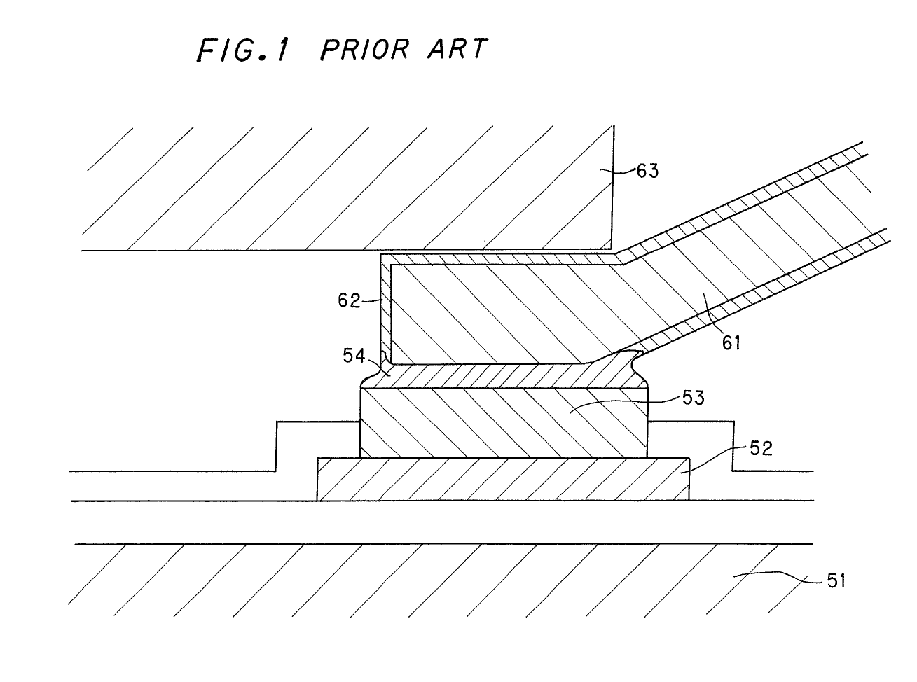

FIG. 2 is a view of an overall configuration showing the connected state of a conductor pattern with a semiconductor chip of a semiconductor device according to the present invention;

FIG. 3 is an enlarged sectional view showing the connected portion between a bump of a semiconductor chip and a conductor lead of a tape carrier;

FIG. 4 is an enlarged sectional view showing the same connected portion between a bump of a semiconductor chip and a conductor lead of a tape carrier, viewed from another direction; and

FIG. 5 is an enlarged sectional view showing the connected portion between a bump of a semiconductor chip and a conductor lead of a tape carrier with a Au layer of a greater thickness.

### DESCRIPTION OF THE PREFERRED EMBODIMENTS

The embodiment of the present invention will hereinafter be described in detail with reference to the accompanying drawings.

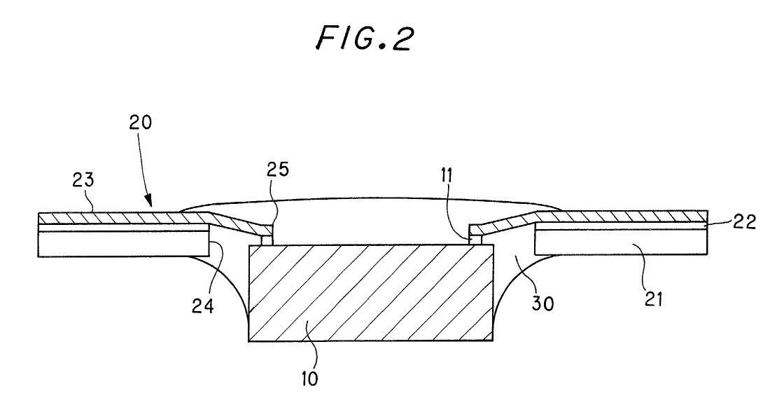

FIG. 2 is a view of an overall configuration showing the connected state of a conductor pattern with a semiconductor chip of a semiconductor device according to the present invention. This semiconductor is of a TCP configuration and is comprised of a semiconductor chip 10 and a tape carrier 20. Formed on semiconductor chip 10 are Ni bumps 11. Tape carrier 20 is comprised of an insulator film 21, an adhesive 22 applied on insulator film 21, a conductor pattern 23 bonded to insulator film 21 with adhesive 22, a device hole 24 which is punched out in insulator film 21 where semiconductor chip 10 is connected, conductor leads 25 extended from the edge of device hole 24 for allowing connection to semiconductor chip 10. The connected portion between semiconductor chip 10 and tape carrier 20 is applied with sealing resin 30.

Here, insulative film 21 employs a film made of polyimide material but other than polyimide materials such as aramid, glass epoxy, BT resin, PET and the like can be used. As to the film thickness, a film of 75 μm or thinner is used. In the present embodiment, a film of 75 μm, made of polyimide material was used. The adhesive having a three layer configuration tape using epoxy material of 13 μm typ., thick was used. Conductor pattern 23 and conductor leads 25 are formed by etching electrolyte copper foil of 18 μm typ., thick. Further, in order to provide insulation, solder resists (not shown) are print applied over conductor pattern 23.

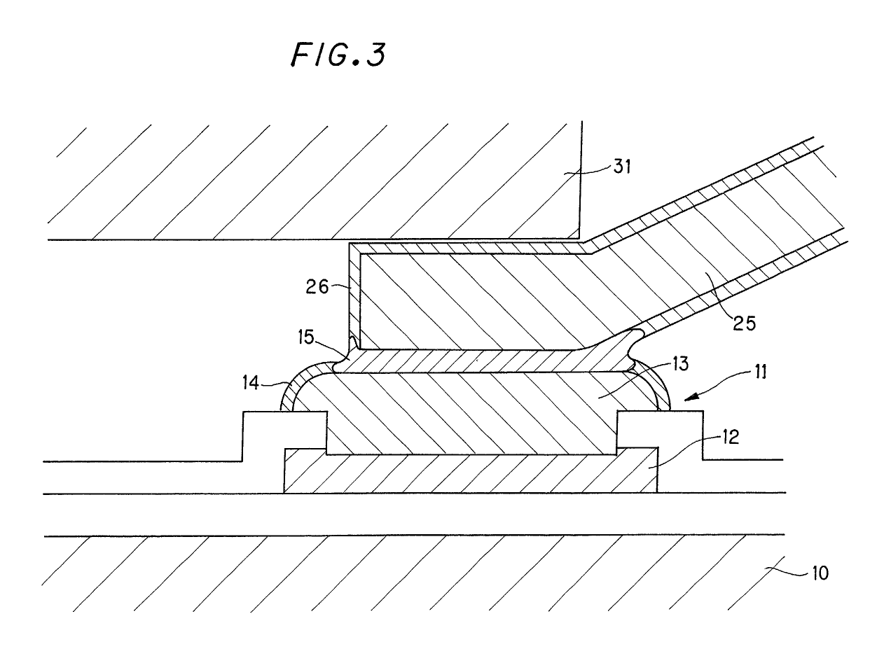

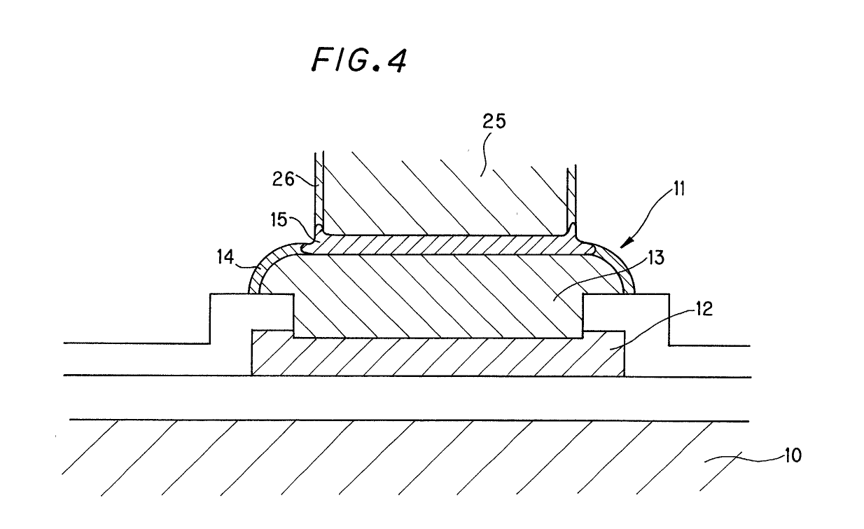

FIGS. 3 and 4 are enlarged views showing the connected portion between bump 11 of semiconductor chip 10 and conductor lead 25 of tape carrier 20. FIG. 3 is an enlarged sectional view of the connected portion shown in FIG. 2 and FIG. 4 is an enlarged sectional view of the same connected portion cut along a plane perpendicular to the document surface of FIG. 2.

Formed on the semiconductor chip 10 surface are electrode pads 12, on which electroless Ni plated bumps 13 are formed. Electroless Ni plated bumps 13 are arranged in at least two rows in parallel with the two sides of semiconductor chip 10 opposing each other. Each electroless Ni plated bump 13 is 5 μm or more in height and the surface is coated with Au plating 14 as a metal film.

The surface of conductor lead 25 is coated with Sn plating 26. Conductor lead 25 and bump 11 are joined by being heated and pressed against each other by a bonding tool 31 to form an Au/Sn eutectic alloy 15.

The thickness of the Au layer should be at least 0.5 μm or greater. In this embodiment, in order to allow beneficial formation of the alloy a Au film 14 of 1.0 μm thick is formed on the surface of electroless Ni plated bump 13. For this Au layer, the thickness of the Sn layer should be 0.09 to 0.19 μm. The junction between bump 11 and conductor lead 25 is formed by formation of Au/Sn eutectic alloy 15. For this formation of the Au/Sn eutectic alloy, a bonding tool 31 heated to about 500° C. is pressed on the side of conductor lead 25 for about 1 second.

For joining bump 11 and conductor lead 25, a preferable component weight ratio of the Au/Sn eutectic alloy is about Au:Sn=8:2, the above conditions (Au of 1.0 μm thick and Sn of 0.09 to 0.19 μm thick, at 500° C. for 1 sec.) correspond to achievement of the above of the preferable component ratio. When Au supply as metal film 14 is insufficient, the amount of Au/Sn eutectic alloy formed in the correct weight ratio becomes insufficient, whereby the joint strength between bump 11 and conductor lead 25 lowers, resulting in an unstable connection. In order to form a sufficient amount of Au/Sn eutectic alloy at the correct weight ratio, a Au layer of at least 0.5 μm thick as a metal film 14 is needed. The Au layer may have any thickness as long as it is 0.5 μm or thicker, but from the view point of cost and reduction in plating time, about 1.3 μm is favorable.

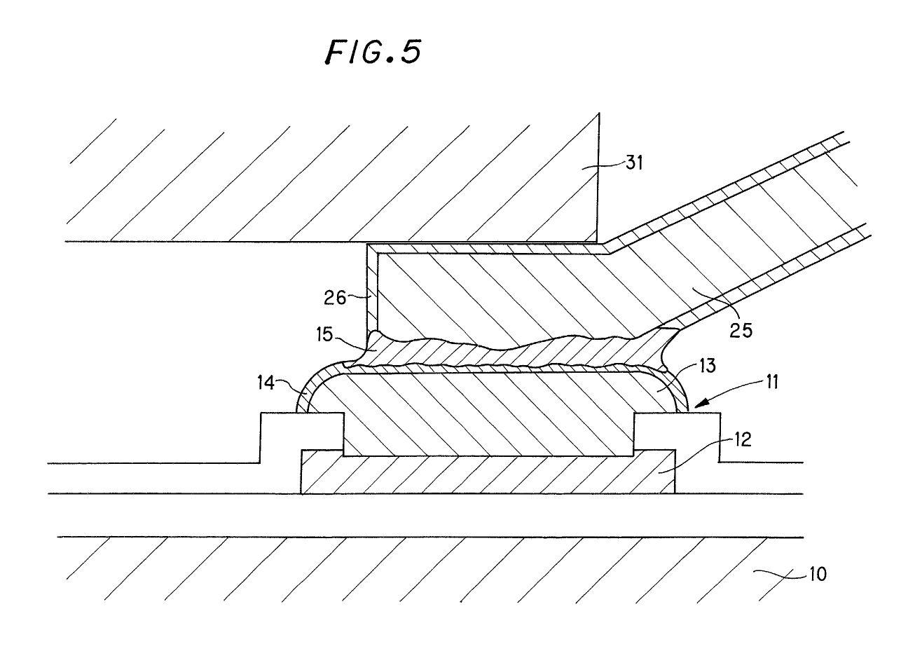

Concerning Sn as a metal film 26 formed on conductor lead 25, in order to produce a sufficient amount of Au/Sn eutectic alloy of the favorable weight ratio, Sn plating of at least 0.09 μm is needed. In this case, however, if an excessive amount of Sn is supplied, brittle Au/Sn eutectic alloy with an overabundance of Sn, deviating from the specified weight ratio of the favorable Au/Sn eutectic alloy, is excessively formed. In this case, lowering of the joint strength between bump 11 and conductor lead 25 due to diffusion of Cu and Sn in conductor lead 25, short-circuit between neighboring junctions due to excessive Au/Sn eutectic alloy, transfer of Au/Sn eutectic alloy to bonding tool 31, and other defects will occur, causing loss of reliability, production yield, productivity, etc. For this reason, the upper boundary of the thickness of Sn as metal film 26 forming conductor lead 25 is specified at 0.19 μm. Even when the Au layer is formed to have a thickness equal to 1.0 μm or greater, the film thickness of Sn may and should be 0.09 to 0.19 μm and does not need to be changed due to the film thickness of Au because only an amount of Au which matches that of the supplied amount of tin will contribute to formation of the eutectic alloy. FIG. 5 shows an enlarged sectional view of the connected portion between a bump of a semiconductor chip and a conductor lead of a tape carrier with a Au layer of a greater thickness.

In the above description of this embodiment, Au is plated over the surface of electroless Ni plated bumps 13 while tin is plated as a metal film over the surface of conductor leads 25, but tin may be plated over the surface of electroless Ni plated bumps 13 while Au is plated as a metal film over the surface of conductor leads 25. Also in this case, the specifications of tin and Au as to metal film thickness should be the same as above.

The above description was made referring to an example of TCP, but the invention can be applied to semiconductor devices having no device hole such as COFs (chip-on-films).

As has been detailed heretofore, specifying the thickness of the metal film formed on Ni bumps and that of the metal film formed on the conductor pattern at the predetermined ratio makes it possible to use semiconductor chips having Ni bumps formed on electrode pads. Thus, without the necessity of changing the conventional assembly process, it is possible to provide low cost semiconductor devices with their conductor leads and semiconductor chip joined by alloy formation.

What is claimed is:

1. A semiconductor device in which bumps formed on a semiconductor chip and a conductor pattern formed on a substrate are connected, characterized in that
the bump is comprised of Ni and a metal film having a thickness falling within a specified range, formed over Ni;
the conductor pattern is coated with a metal film having a thickness falling within a specified range; and
the connection is formed by alloying the metal films.

2. The semiconductor device according to claim 1, wherein the metal film on the bumps is Au and the metal film on the conductor pattern is Sn.

3. The semiconductor device according to claim 1, wherein the metal film on the bumps is Sn and the metal film on the conductor pattern is Au.

4. The semiconductor device according to claim 2, wherein the metal film of Au is 0.5 to 3.0 μm thick and the metal film of Sn is 0.09 to 0.19 μm thick.

5. The semiconductor device according to claim 3, wherein the metal film of Au is 0.5 to 3.0 μm thick and the metal film of Sn is 0.09 to 0.19 μm thick.
